(19) United States
(12) Patent Application Publication
(10) Pub. No.: US 2015/0040826 A1
(43) Pub. Date: Feb. 12, 2015

(54) METHOD FOR MANUFACTURING METAL MASK

(71) Applicant: Samsung Display Co., Ltd., Yongin-City (KR)

(72) Inventors: Sung-Woo JUNG, Yongin-City (KR); Sang-Yun LEE, Yongin-City (KR); Yong-Hwan KIM, Yongin-City (KR)

(73) Assignee: Samsung Display Co., Ltd., Yongin-City (KR)

(21) Appl. No.: 14/248,483

(22) Filed: Apr. 9, 2014

(30) Foreign Application Priority Data
Aug. 6, 2013 (KR) 10-2013-0093177

(51) Int. Cl. C23F 1/02; G03F 7/30; G03F 7/40; B05C 21/00

(52) U.S. Cl. CPC C23F 1/02; B05C 21/005; G03F 7/30; G03F 7/40
USPC 118/504; 216/12; 430/320

(57) ABSTRACT

A method for manufacturing a metal mask includes defining pattern areas exposing an upper surface, and a lower surface opposite to the upper surface, of a thin plate; and etching the upper and lower surfaces of the thin film plate exposed by the pattern areas, to reduce a thickness of the thin film plate by a predetermined thickness and form deposition openings in the metal mask. The etching the upper and lower surfaces of the thin film plate includes both a wet-etching method and a dry-etching method.

This application claims priority to Korean Patent Application No. 10-2013-0093177 filed on Aug. 6, 2013, and all the benefits accruing therefrom under 35 U.S.C. §119, the entire contents of which are incorporated herein by reference.

### BACKGROUND

(a) Field

The invention relates to a method for manufacturing a metal mask.

(b) Description of the Related Art

A display device is a device displaying an image, and an organic light emitting diode (“OLED”) display has received attention as a display device.

Since the OLED display has a self-emission characteristic and does not employ a separate light source unlike a liquid crystal display device, thickness and weight thereof may be reduced. Further, the OLED display has high-quality characteristics such as low power consumption, high luminance and a high response speed.

In manufacturing such an OLED display, a metal mask may be used to form organic emission layers such as colored organic emission layers of red (R), green (G), and blue (B).

In manufacturing the OLED display, an organic emission layer of one color is formed using a metal mask where an opening having a size that corresponds to a size of one pixel in the OLED display is formed, and then organic emission layers of other colors can be formed by moving the metal mask according to each pixel cell in the OLED display.

### SUMMARY

One or more exemplary embodiment of the invention provides a method for manufacturing a metal mask that can precisely control the size of an opening which is defined in the metal mask and is used to form a pattern of a display device.

One exemplary embodiment of the invention provides a method for manufacturing a metal mask. The method includes defining pattern areas exposing an upper surface, and a lower surface opposite to the upper surface, of a thin plate; and etching the upper and lower surfaces of the thin film plate exposed by the pattern areas, to reduce a thickness of the thin film plate by a predetermined thickness and form deposition openings in the metal mask. The etching the upper and lower surfaces of the thin film plate includes both a wet-etching method and a dry-etching method.

The etching the upper and lower surfaces of the thin film plate may further include: dry-etching the upper surface of the thin film plate exposed by a first pattern area to reduce the thickness of the thin film plate by a first predetermined thickness; covering the upper surface of the dry-etched thin film plate with a protection member; wet-etching the lower surface of the thin film plate exposed by a second pattern area to reduce the thickness of the thin film plate by a second predetermined thickness, with the protection member covering the upper surface of the dry-etched thin film plate; and removing the protection member.

In the wet-etching, the lower surface of the thin film plate may expose the protection member covering the upper surface of the dry-etched thin film plate.

A width of the first pattern area may be smaller than a width of the second pattern area.

The defining pattern areas may include using a photoresist.

The defining pattern areas may further include: cleaning the upper and lower surfaces of the thin plate; coating the photoresist on the upper and lower surfaces of the thin plate; exposing the photoresist to define the pattern areas; and developing the exposed photoresist.

After the etching the upper and lower surfaces of the thin film plate, the method may further include removing the photoresist coated on the upper and lower surfaces of the thin plate.

In a metal mask manufactured by the above-stated method, the deposition openings may be openings through which an organic emission layer of an organic light emitting device is deposited.

According to one or more exemplary embodiment of the invention, the pattern areas defined in the thin plate are formed by etching the thin film plate using both a wet-etching method and a dry-etching method, so that the openings in the thin film plate can be more precisely formed.

### BRIEF DESCRIPTION OF THE DRAWINGS

The above and other features of this disclosure will become more apparent by describing in further detail exemplary embodiments thereof with reference to the accompanying drawings, in which:

FIG. 1 is a plan view of an exemplary embodiment of a metal mask according to the invention.

FIG. 2 is an enlarged view of part II of FIG. 1.

FIG. 3 is a cross-sectional view of FIG. 2, taken along line III-III′.

FIG. 4 to FIG. 8 show an exemplary embodiment of an etching process in a process of manufacturing a metal mask according to the invention.

### DETAILED DESCRIPTION

The invention will be described more fully hereinafter with reference to the accompanying drawings, in which exemplary embodiments of the invention are shown. As those skilled in the art would realize, the described exemplary embodiments may be modified in various different ways, all without departing from the spirit or scope of the invention.

Parts that are irrelevant to the description will be omitted to clearly describe the invention, and the same elements will be designated by the same reference numerals throughout the specification.

In addition, the size and thickness of each configuration shown in the drawings are arbitrarily shown for better understanding and ease of description, but the invention is not limited thereto.

In the drawings, the thickness of layers, films, panels, regions, etc., are exaggerated for clarity. In the drawings, for better understanding and ease of description, the thickness of some layers and areas is exaggerated. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. Further, in the specification, the word “on” means positioning on or below the object portion, but does not essentially mean positioning on the upper side of the object portion based on a gravity direction.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

In general, in manufacturing a metal mask, a pattern of the metal mask, that is, an opening defined in the metal mask and through which an organic light emission material is provided, is formed using a wet-etching method. However, as the resolution of the organic light emitting diode display is increased, the size of the opening in the metal mask needs to be precisely controlled in manufacturing of the metal mask. Therefore, there remains a need for an improved method of manufacturing a metal mask for deposition in which openings are precisely formed by the method.

An exemplary embodiment of a method for manufacturing a metal mask according to the invention will be described hereinafter, with reference to the drawings.

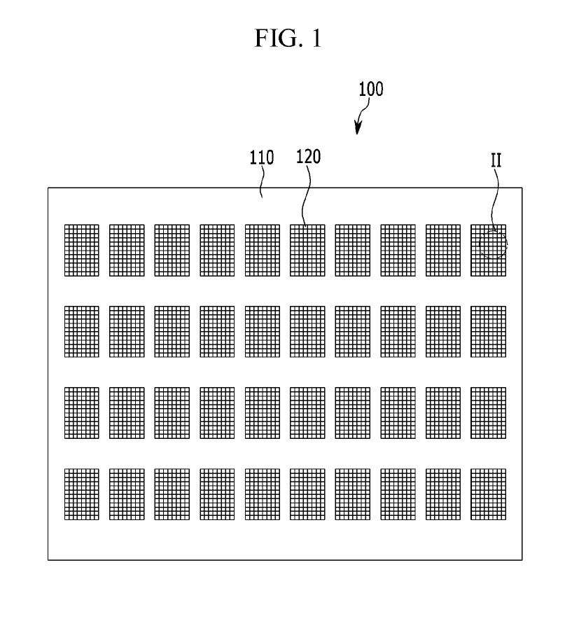

FIG. 1 is a plan view of an exemplary embodiment of a metal mask.

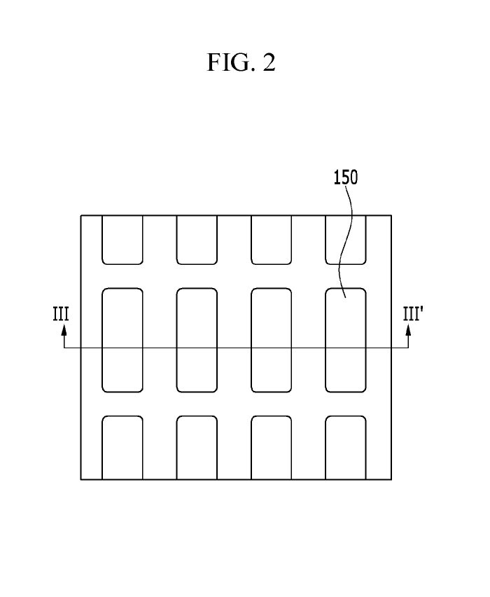

FIG. 2 is an enlarged view of part II of FIG. 1.

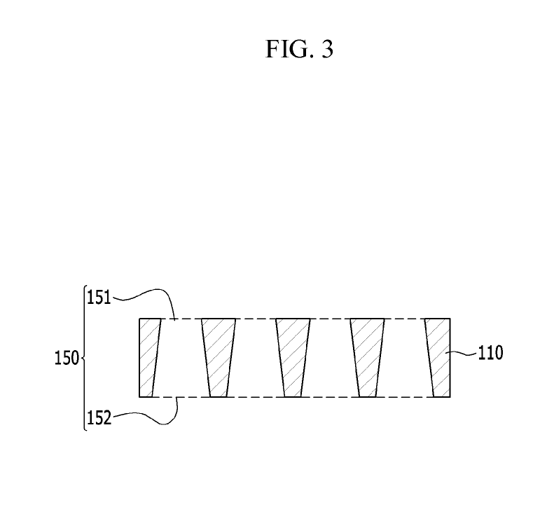

FIG. 3 is a cross-sectional view of FIG. 2, taken along line III-III′.

Referring to FIG. 1, a metal mask 100 may include a plurality of deposition portions 120 defined in a thin plate 110. The plurality of deposition portions 120 are arranged in the thin plate 110, such as in a matrix form having rows and columns, but the invention is not limited thereto.

According to the exemplary embodiment of the invention, the thin plate 110 may include an invar material.

Here, the invar material is an alloy formed of 63.8% Fe, 36% Ni, and 0.2% C, and has a very low thermal expansion coefficient.

In addition, according to the exemplary embodiment of the invention, the deposition portions 120 may be portions of the metal mask through which organic light emission materials are deposited on a substrate. The substrate may be a substrate of an organic light emitting diode (“OLED”) display, but is not limited thereto.

Referring to FIG. 2 and FIG. 3 relating to the OLED display, each deposition portion 120 includes a plurality of openings 150 defined in the thin plate 110. A deposition portion 120 may also be defined by a group of openings 150. Each of the openings 150 has a size that corresponds to a pixel cell area of the OLED display.

In FIG. 2, each opening 150 has a rectangular shape in the plan view, but this is not restrictive of the invention. The openings 150 may have various planar shapes that can enable effective deposition of the organic light emission material therethrough.

The plurality of openings 150 may be arranged at a distance from each other, that is, separated from each other. The groups of the openings 150 may also be spaced apart from each other. Portions of the thin plate 110 define the openings 150 and are between adjacent openings 150.

In addition, according to the exemplary embodiment of the invention, with reference to a cross-sectional view shown in FIG. 3, the plurality of openings 150 includes first opening portions 151 defined in an upper portion of the thin plate 110 and second opening portions 152 defined in a lower portion of the thin plate 110. Referring to the rectangular shape of the openings 150 in FIG. 2, each opening has a length dimension which is larger than a width dimension. A width of each of the first opening portions 151 may be narrower than a width of each of the second opening portions 152, as illustrated in FIG. 3.

The first opening portions 151 have the narrower widths than the second opening portions 152 to not restrict or limit an incident angle of deposition. If the incident angle is limited during a deposition process of the organic light emission material through the openings 150, a uniform deposition layer may not be formed.

An upper direction and a lower direction in the specification are defined with reference to the vertical direction in FIG. 3.

Hereinafter, an exemplary embodiment of a method for manufacturing a metal mask according to an exemplary embodiment of the invention will be described.

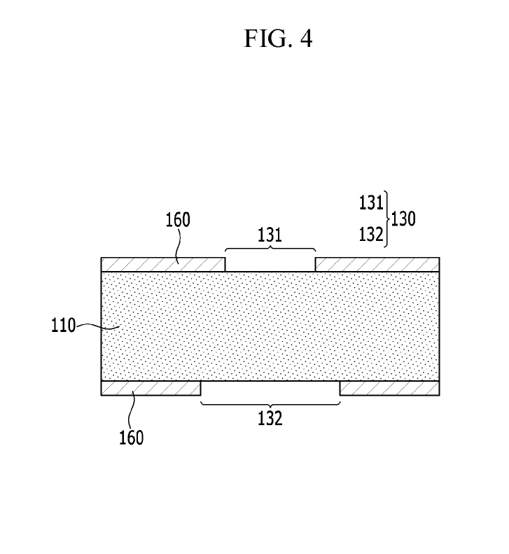

FIG. 4 to FIG. 8 show an exemplary embodiment of etching processes in a method for manufacturing a metal mask according to the invention.

An exemplary embodiment of a method for manufacturing a metal mask according to the invention includes an operation (hereinafter referred to as a first operation) for forming pattern areas 130 at both of opposing sides of the thin plate 110 and an operation (hereinafter referred to as a second operation) for etching portions of the thin plate 110 at the pattern areas 130 to a predetermined thickness.

FIG. 4 shows that the pattern areas 130 are formed (e.g., provided) at both of opposing sides of the thin film 110, through the first operation.

According to the exemplary embodiment of the invention, the pattern areas 130 may be formed using a photoresist 160 in the first operation. Portions of the photoresist 160 may define the pattern areas 130 with respect to the thin film 110

Here, the photoresist 160 includes a material that causes a chemical change when exposed to light, and is classified as a negative type photoresist that is changed to insoluble to chemicals when exposed to light, and a positive type photoresist that is changed to soluble to chemicals when exposed to light.

In the first operation, as shown in FIG. 4, a first pattern area 131 is formed at the upper surface of the thin plate 110 and a second pattern area 132 is formed at the bottom surface of the thin plate 110, using the photoresist 160. The photoresist 160 exposes portions of the thin film plate 110 at the first and second pattern areas 131 and 132.

Referring to the cross-sectional view of the thin film 110 in FIG. 4, the width of the first pattern area 131 may be narrower than the width of the second pattern area 132.

The first operation using the photoresist 160 may include a cleaning process, a coating process, an exposing process and a developing process, and the processes may be sequentially performed.

First, the cleaning process is performed to clean the both opposing sides of the thin film 110 where the pattern areas 130 will be formed.

In the coating process, the photoresist 160 is coated to the both opposing sides of the thin plate 110.

In the exposing process, light is irradiated to the photoresist 160 coated to the both opposing sides of the thin plate 110.

The photoresist 160 may be exposed to the light depending on a pattern area 130 to be formed.

In one exemplary embodiment, for example, a photomask having a pattern is positioned on the photoresist 160 and the light is irradiated such that portions of the coated photoresist 160 can be exposed by the photomask depending on the pattern area 130 to be formed.

Alternatively, pattern design information is input to a light irradiation apparatus and light can be set to be irradiated to the coated photoresist corresponding to a designed pattern shape.

Then, the exposed photoresist 160 is developed through the last process of the first operation, that is, the developing process.

When the photoresist 160 is a negative type photoresist 160, portions of the photoresist material excluding the pattern area 130 remain through the developing process.

In contrast, when the photoresist 160 is a positive type photoresist 160, only portions of the photoresist material at the pattern area 130 remain through the developing process.

In the exemplary embodiment of the invention, as shown in FIG. 4, the negative type photoresist 160 is used.

Next, the second operation will be described in detail.

In the exemplary embodiment of the method for manufacturing the metal mask according to the invention, portions of the thin plate 110 at the pattern areas 130 formed at the both opposing sides of the thin plate 110 through the first operation are etched to a predetermined thickness during the second operation.

According to the exemplary embodiment of the invention, in the second operation, the portions of the thin film plate 110 at the pattern areas 130 may be etched using both a wet-etching method and a dry-etching method.

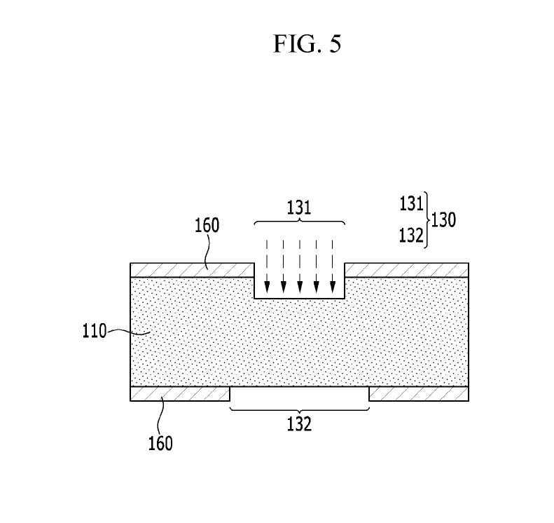

In further detail, referring to FIG. 5, a portion of the thin film plate 110 at the first pattern area 131 is etched to a predetermined thickness using the dry-etching method. The photoresist 160 defining the first pattern area 131 is used as an etching mask. In the etching, a cross-sectional thickness of the thin film plate 110 is reduced by the predetermined thickness from the upper surface, forming a recessed portion in the thin film plate 110.

The dry-etching method is a method for etching a target material to be eliminated by changing the target material to a volatile gas by exposing a reactive gas in plasma, instead of using a liquid chemical material.

Here, the drying etching is anisotropic etching, and therefore, as shown in FIG. 5, a portion of the thin film plate 110 below the photoresist 160 defining the first pattern area 131 is not etched, and a width of the thin film plate 110 that is equivalent to the width of the first pattern area 131 is etched and removed in the dry etching.

Thus, since the width of the first pattern area 131 may be formed to be constant, the etched width of the thin film plate 110 can be more precisely controlled in the dry etching than with the wet-etching.

In addition, since the etched width of the thin film plate 110 is constant, the organic light emission material can be more uniformly and precisely deposited during a subsequent deposition process.

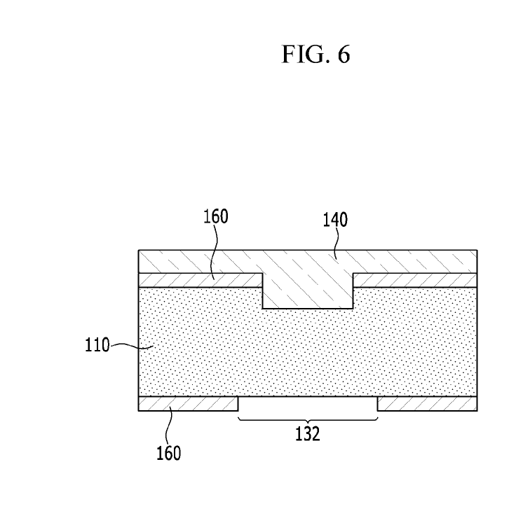

After the dry-etching is performed to reduce the thickness of the thin film plate 110 to a thickness that is appropriate for the deposition process, referring to FIG. 6, the recess in the thin film plate 110 at the first pattern area 131 where the dry-etching was performed is filled and covered by a protection member 140.

The side of the thin plate 110 at which the first pattern area 131 is defined may be entirely covered the by protection member 140, so that the side is not exposed to a liquid chemical material during wet-etching.

The protection member 140 includes a material that does not react with the liquid chemical material used in the wet-etching.

According to the exemplary embodiment of the invention, the protection member 140 may include a resin, but this is not restrictive. A photoresist may be used as the protection member 140.

Accordingly, since the exposed portion of the thin film plate 110 is covered by the protection member 140 at the first pattern area 131, damage to the exposed portion of the thin film plate 110 by the liquid chemical material that performs the wet-etching may be reduced or effectively prevented.

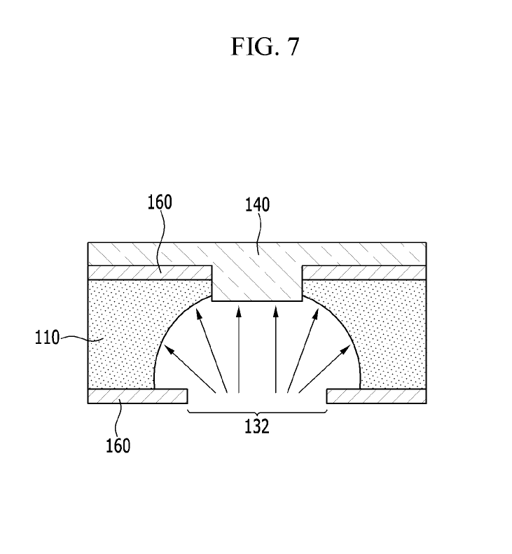

Subsequently, referring to FIG. 7, bottom surface portions of the thin film plate 110 exposed by the second pattern area 132 are etched using the wet-etching method.

The wet-etching method is a method for etching by selectively dissolving a portion of the overall target material to be eliminated using a liquid chemical material.

Here, the wet-etching method is an anisotropic etching method, and therefore as shown in FIG. 7, a portion of the thin film plate 110 above the photoresist 160 forming the second pattern area 132 is also etched. Therefore, a width of the thin film plate 110 removed by the wet-etching may be larger than the width of the second pattern area 132.

Thus, the etching process of portions of the thin film plate 110 at the second pattern area 132 is less controlled as compared to the etching at the first pattern area 131.

As described above, the wet-etching method has low precision compared to the dry-etching method, but the wet-etching method has merits of employing relatively inexpensive process equipment and being a relatively simple process.

Thus, in the exemplary embodiment of manufacturing the metal mask according to the invention, only a relatively narrow opening that employs precision in manufacturing of the metal mask 100, that is, at the first pattern area 131, is precisely etched using the dry-etching method, and a relatively wide opening that can be formed with less precision in manufacturing, that is, at the second pattern area 132, is etched using the wet-etching method so that precision of the metal mask 100 can be effectively and economically controlled and improved.

Referring to FIG. 7, the wet-etching process of the thin film plate 110 at the second pattern area 132 etches the thin film plate 110 to a thickness that exposes the protection member 140 covering a groove portion formed in the thin film plate 110 from the dry-etching at the first pattern area 131.

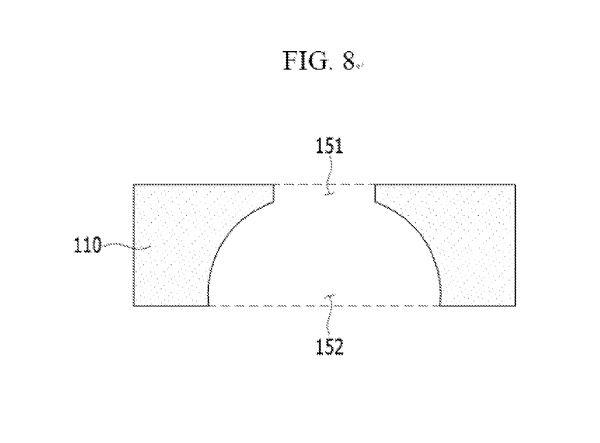

Thus, an opening 150 that connects the first opening portion 151 formed by the first pattern area 131 and the second opening portion 152 formed by the second pattern area 132, may be formed (refer to FIG. 8).

The protection member 140 is removed from the thin plate 110. The removing of the protection member 140 reveals a continuous opening 150 penetrating both the upper and lower surfaces of the thin film plate 110.

Through the above-described process, the second operation is finished.

As shown in FIG. 8 the exemplary embodiment of the method for manufacturing the metal mask according to the invention may further include an operation (hereinafter referred to as a third operation) for removing the photoresist 160 coated on the both opposing sides of the thin plate 110 from the thin plate 110. The removing of the photoresist 160 may also reveal the continuous opening 150 penetrating both the upper and lower surfaces of the thin film plate 110.

After the third operation is finished, referring to FIG. 8, the first opening portion 151 having a relatively narrow width is formed in the upper surface of the thin plate 110 and the second opening portion 152 having a relatively wide width is formed in the bottom surface of the thin plate 110.

As described, one or more exemplary embodiment of the method for manufacturing the metal mask according to the invention employs both wet-etching and dry-etching to etch the thin film plate 110 at the pattern area 130 so that the metal mask having improved precision can be economically and effectively manufactured.

In further detail, according to one or more exemplary embodiment of the invention, the narrow opening that employs precision in manufacturing is formed by using the dry-etching method and the wide opening that can employ less precision in manufacturing as compared to the narrow opening formed by using the wet-etching method so that the opening 150 of the metal mask 100 can be more precisely and economically formed.

While this invention has been described in connection with what is presently considered to be practical exemplary embodiments, it is to be understood that the invention is not limited to the disclosed exemplary embodiments, but, on the contrary, is intended to cover various modifications and equivalent arrangements included within the spirit and scope of the appended claims.

What is claimed is:

1. A method for manufacturing a metal mask, comprising:
defining pattern areas exposing an upper surface, and a lower surface opposite to the upper surface, of a thin plate; and
etching the upper and lower surfaces of the thin film plate exposed by the pattern areas, to reduce a thickness of the thin film plate by a predetermined thickness and form deposition openings in the metal mask,
wherein the etching the upper and lower surfaces of the thin film plate comprises both a wet-etching method and a dry-etching method.

2. The method for manufacturing the metal mask of claim 1, wherein the etching the upper and lower surfaces of the thin film plate further comprises:
dry-etching the upper surface of the thin film plate exposed by a first pattern area to reduce the thickness of the thin film plate by a first predetermined thickness;
covering the upper surface of the dry-etched thin film plate with a protection member;
wet-etching the lower surface of the thin film plate exposed by a second pattern area to reduce the thickness of the thin film plate by a second predetermined thickness, with the protection member covering the upper surface of the dry-etched thin film plate; and
removing the protection member.

3. The method for manufacturing the metal mask of claim 2, wherein in the wet-etching, the lower surface of the thin film plate exposes the protection member covering the upper surface of the dry-etched thin film plate.

4. The method for manufacturing the metal mask of claim 2, wherein a width of the first pattern area is smaller than a width of the second pattern area.

5. The method for manufacturing the metal mask of claim 1, wherein the defining pattern areas comprises using a photoresist.

6. The method for manufacturing the metal mask of claim 5, wherein the defining pattern areas further comprises:
cleaning the upper and lower surfaces of the thin plate;
coating the photoresist on the upper and lower surfaces of the thin plate;
exposing the photoresist to define the pattern areas; and
developing the exposed photoresist.

7. The method for manufacturing the metal mask of claim 6, further comprising, after the etching the upper and lower surfaces of the thin film plate, removing the photoresist coated on the upper and lower surfaces of the thin plate.

8. A metal mask manufactured by the method for manufacturing the metal mask of claim 1,
wherein the deposition openings are openings through which an organic emission layer of an organic light emitting device is deposited.

9. A metal mask for deposition, comprising:
a plurality of deposition portions defined in a thin plate and through which an organic emission layer of an organic light emitting device is deposited,
wherein each deposition portion comprises a group of openings defined in the thin plate.

10. The metal mask for deposition of claim 9, wherein
a dry-etched width at an upper surface of the thin film plate of an opening among the group of openings is smaller than a wet-etched width at a lower surface of the thin film plate opposite to the upper surface of the opening.
